(19) United States
(12) Patent Application Publication
(10) Pub. No.: US 2020/0098824 A1
(43) Pub. Date: Mar. 26, 2020

(54) DIODE BASED RESISTIVE RANDOM ACCESS MEMORY

(71) Applicants: Abhishek SHARMA, Hillsboro, OR (US); Gregory K. CHEN, Portland, OR (US); Ram KRISHNAMURTHY, Portland, OR (US); Ravi PILLARISETTY, Portland, OR (US); Sasikanth MANIPATRUNI, Portland, OR (US); Amrita MATHURIYA, Portland, OR (US); Raghavan KUMAR, Hillsboro, OR (US); Phil KNAG, Hillsboro, OR (US); Huseyin SUMBUL, Portland, OR (US); Urusa ALAAN, Hillsboro, OR (US); Noriyuki SATO, Hillsboro, OR (US)

(72) Inventors: Abhishek SHARMA, Hillsboro, OR (US); Gregory K. CHEN, Portland, OR (US); Ram KRISHNAMURTHY, Portland, OR (US); Ravi PILLARISETTY, Portland, OR (US); Sasikanth MANIPATRUNI, Portland, OR (US); Amrita MATHURIYA, Portland, OR (US); Raghavan KUMAR, Hillsboro, OR (US); Phil KNAG, Hillsboro, OR (US); Huseyin SUMBUL, Portland, OR (US); Urusa ALAAN, Hillsboro, OR (US); Noriyuki SATO, Hillsboro, OR (US)

(21) Appl. No.: 16/142,040

(22) Filed: Sep. 26, 2018

(51) Int. Cl. H01L 27/24; H01L 45/00

(52) U.S. Cl. CPC H01L 27/2409; H01L 45/1253; H01L 45/1233; H01L 27/2481; H01L 45/144; H01L 45/1608; H01L 45/146

(57) ABSTRACT

Embodiments herein describe techniques for a semiconductor device including a RRAM memory cell. The RRAM memory cell includes a substrate, a RRAM storage cell above the substrate, and a diode adjacent to the RRAM storage cell. The RRAM storage cell includes a first electrode located in a first metal layer above the substrate, a resistive switching material layer adjacent to the first electrode, and a second electrode adjacent to the resistive switching material layer. The second electrode is shared between the RRAM storage cell and the diode. The diode includes the second electrode shared with the RRAM storage cell, a semiconductor layer adjacent to the second electrode, and a third electrode located in a second metal layer above the substrate. Other embodiments may be described and/or claimed.

### FIELD

Embodiments of the present disclosure generally relate to the field of integrated circuits, and more particularly, to resistive random access memory (RRAM).

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

Resistive random access memory (RRAM) is an emerging technology for next generation non-volatile (NV) random-access memory (RAM). A RRAM memory cell may include a RRAM storage cell coupled to a selector. However, when a Si transistor is used as the selector, a RRAM memory cell may be area inefficient. Moreover, with devices scaling down, the Si transistor used as the selector may leak static power.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a three-dimensional view of a resistive random access memory (RRAM) array including multiple RRAM memory cells, in accordance with various embodiments.

FIGS. 2(a)-2(c) schematically illustrate a three-dimensional view or cross-section views of a RRAM memory cell including a diode and a RRAM storage cell, in accordance with various embodiments.

FIG. 3 illustrates a diagram of a process for forming a RRAM memory cell including a diode and a RRAM storage cell, in accordance with some embodiments.

FIG. 4 schematically illustrates a diagram of a RRAM memory cell including a diode and a RRAM storage cell formed in back-end-of-line (BEOL) on a substrate, in accordance with some embodiments.

FIG. 5 schematically illustrates an interposer implementing one or more embodiments of the disclosure, in accordance with some embodiments.

FIG. 6 schematically illustrates a computing device built in accordance with an embodiment of the disclosure, in accordance with some embodiments.

### DETAILED DESCRIPTION

Resistive random access memory (RRAM) is an emerging technology for next generation non-volatile (NV) random-access memory (RAM). A RRAM array may include multiple RRAM memory cells. A RRAM memory cell may include a RRAM storage cell coupled to a selector. A RRAM memory cell may store data based on the resistance values of the RRAM storage cell within the RRAM memory cell. A RRAM memory cell may be programmed to a particular resistance value to store a logic value, e.g., “0” or “1”. The stored logic value of a RRAM memory cell may be read, for example, by determining current through the selected RRAM memory cell responsive to a voltage applied to the RRAM memory cell.

A RRAM memory cell may have various structures, including different RRAM storage cells coupled to different selectors. For example, a RRAM memory cell may include a 1T1R (one transistor/one resistor) configuration, or a 1D1R (one diode/one resistor) configuration. Under the 1D1R configuration, a RRAM memory cell may include a RRAM storage cell coupled to a diode as a selector. A RRAM memory cell in the 1D1R configuration may result in a denser structure compared to a RRAM memory cell in the 1T1R configuration. However, there may be other issues related to a RRAM memory cell in the 1D1R configuration, such as signal qualities.

Embodiments herein may present a RRAM memory cell at the back-end-of-line (BEOL) on a substrate. The RRAM memory cell includes a RRAM storage cell and a diode adjacent to the RRAM storage cell. An electrode is shared between the RRAM storage cell and the diode. By sharing the electrode, the RRAM memory cell may reduce disturbance effects by filtering out noise induced by inhibitory or weak excitatory signals of the RRAM storage cell. Accordingly, the RRAM memory cell in such a 1D1R configuration may have a dense area with improved signal qualities.

Embodiments herein may present a RRAM memory cell including a substrate, a RRAM storage cell above the substrate, and a diode adjacent to the RRAM storage cell. The RRAM storage cell includes a first electrode located in a first metal layer above the substrate, a resistive switching material layer adjacent to the first electrode, and a second electrode adjacent to the resistive switching material layer. The second electrode is shared between the RRAM storage cell and the diode. In detail, the diode includes the second electrode shared with the RRAM storage cell, a semiconductor layer adjacent to the second electrode, and a third electrode located in a second metal layer above the substrate.

Embodiments herein may present a RRAM array including a plurality of RRAM memory cells. A RRAM memory cell of the plurality of RRAM memory cells includes a diode and a RRAM storage cell. The RRAM storage cell includes a first electrode located in a first metal layer above a substrate, a resistive switching material layer adjacent to the first electrode, and a second electrode adjacent to the resistive switching material layer. The first electrode of the RRAM storage cell is coupled to a bit line. The diode is adjacent to the RRAM storage cell and includes the second electrode, a semiconductor layer adjacent to the second electrode, and a third electrode located in a second metal layer above the substrate. The third electrode is coupled to a word line of the RRAM array.

In embodiments, a method for forming a RRAM device may include forming a first electrode located in a first metal layer above a substrate, forming a resistive switching material layer adjacent to the first electrode, and forming a second electrode adjacent to the resistive switching material layer. Accordingly, the first electrode, the resistive switching material layer, and the second electrode form a RRAM storage cell. The method may further include forming a semiconductor layer adjacent to the second electrode, and forming a third electrode located in a second metal layer above the substrate. As a result, the second electrode, the semiconductor layer, and the third electrode form a diode.

Embodiments herein may present a computing device, which may include a circuit board, and a memory device coupled to the circuit board and including a plurality of RRAM memory cells. A RRAM memory cell of the plurality of RRAM memory cells includes a diode and a RRAM storage cell. The RRAM storage cell includes a first electrode located in a first metal layer above a substrate, a resistive switching material layer adjacent to the first electrode, and a second electrode adjacent to the resistive switching material layer. The first electrode of the RRAM storage cell is coupled to a bit line. The diode is adjacent to the RRAM storage cell and includes the second electrode, a semiconductor layer adjacent to the second electrode, and a third electrode located in a second metal layer above the substrate. The third electrode is coupled to a word line of the RRAM array.

In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure. However, the order of description should not be construed to imply that these operations are necessarily order dependent. In particular, these operations may not be performed in the order of presentation.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

As used herein, the term “circuitry” may refer to, be part of, or include an Application Specific Integrated Circuit (ASIC), an electronic circuit, a processor (shared, dedicated, or group), and/or memory (shared, dedicated, or group) that execute one or more software or firmware programs, a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

Implementations of the disclosure may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, zinc oxide or other combinations of group III-V, II-VI, group IV, or semiconducting oxide materials. Although a few examples of materials from which the substrate may be formed are described here, any material that may serve as a foundation upon which a semiconductor device may be built falls within the spirit and scope of the present disclosure.

A plurality of transistors, such as metal-oxide-semiconductor field-effect transistors (MOSFET or simply MOS transistors), may be fabricated on the substrate. In various implementations of the disclosure, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the disclosure may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type work function metal or N-type work function metal, depending on whether the transistor is to be a PMOS or an NMOS transistor. In some implementations, the gate electrode layer may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a work function that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a work function that is between about 3.9 eV and about 4.2 eV.

In some implementations, when viewed as a cross-section of the transistor along the source-channel-drain direction, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the disclosure, the gate electrode may consist of a combination of U-shaped structures and planar, non-U-shaped structures. For example, the gate electrode may consist of one or more U-shaped metal layers formed atop one or more planar, non-U-shaped layers.

In some implementations of the disclosure, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process operations. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

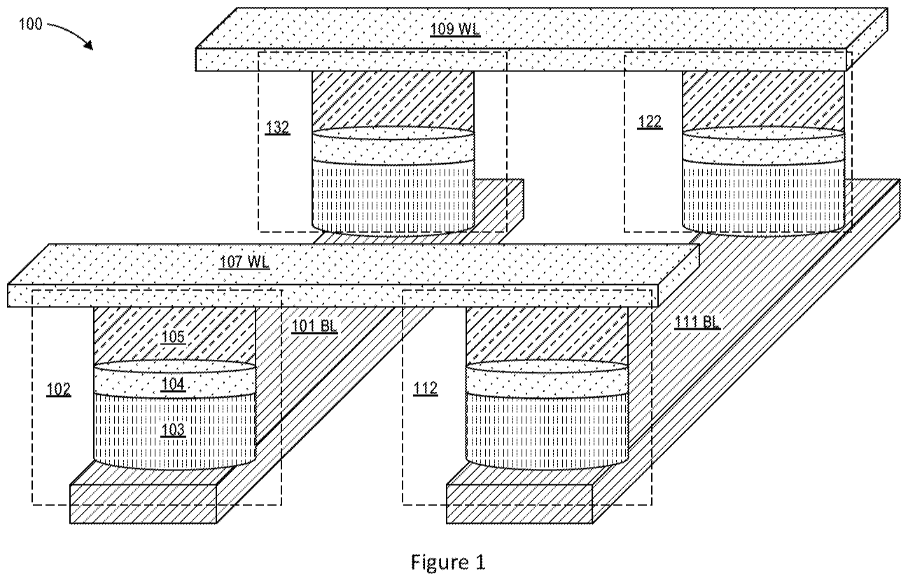

FIG. 1 schematically illustrates a three-dimensional view of a RRAM array 100 including multiple RRAM memory cells, e.g., a RRAM memory cell 102, a RRAM memory cell 112, a RRAM memory cell 122, and a RRAM memory cell 132, in accordance with various embodiments. For clarity, features of the RRAM array 100, the RRAM memory cell 102, the RRAM memory cell 112, the RRAM memory cell 122, and the RRAM memory cell 132 may be described below as examples for understanding an example RRAM array including multiple RRAM memory cells. It is to be understood that there may be more or fewer components within a RRAM array or RRAM memory cells. Further, it is to be understood that one or more of the components within a RRAM array, or RRAM memory cells, may include additional and/or varying features from the description below, and may include any device that one having ordinary skill in the art would consider and/or refer to as a RRAM array or RRAM memory cells.

In embodiments, the RRAM array 100 may be a two terminal cross-point array having RRAM memory cells located at the intersections of a number of word lines, e.g., a word line 107 and a word line 109, and a number of bit lines, e.g., a bit line 101 and a bit line 111. As illustrated, the word line 107 and the word line 109 may be parallel to each other. The word line 107 and the word line 109 may be orthogonal to the bit line 101 and the bit line 111, which may be parallel to each other.

The RRAM memory cell 102 may be coupled in series with other RRAM memory cells, e.g., the RRAM memory cell 112, of the same row, and may be coupled in parallel with the RRAM memory cells of the other rows, e.g., the RRAM memory cell 122 and the RRAM memory cell 132. The RRAM array 100 may include any suitable number of one or more RRAM memory cells. Although the RRAM array 100 is shown in FIG. 1 with two rows that each includes two RRAM memory cells coupled in series, other embodiments may include other numbers of rows and/or numbers of RRAM memory cells within a row. In some embodiments, the number of rows may be different from the number of columns in a RRAM array. Each row of the RRAM array may have a same number of RRAM memory cells. Additionally, or alternatively, different rows may have different numbers of RRAM memory cells.

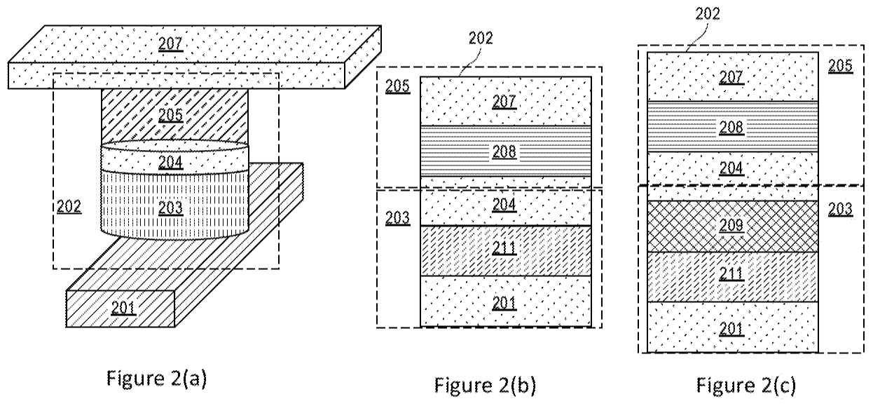

In embodiments, multiple RRAM memory cells, such as the RRAM memory cell 102, the RRAM memory cell 112, the RRAM memory cell 122, and the RRAM memory cell 132, may have a similar configuration, such as the 1D1R configuration. For example, the RRAM memory cell 102 may include a RRAM storage cell 103 and a diode 105 with a shared electrode 104. The RRAM storage cell 103 includes a resistive switching material layer, and the diode 105 includes a semiconductor layer. More details of a RRAM storage cell and a diode are shown in FIGS. 2(a)-2(c). Hence, the RRAM memory cell 102 integrates the diode 105 as a selector with the RRAM storage cell 103. A RRAM storage cell may be referred to simply as a storage cell.

In embodiments, the diode 105 may be a selector for the RRAM memory cell 102. When the word line 107 is active, the diode 105 may select the storage cell, which is the RRAM storage cell 103. A signal from the word line 107 may pass through the diode 105, further through the RRAM storage cell 103, and reaching the other electrode, which is the bit line 101.

In embodiments, the RRAM memory cell 102 may be switchable between two or more resistance values upon application of an electric current or voltage. For example, the RRAM memory cell 102 may have a first resistance value to store a logic 0, and may have a second resistance value to store a logic 1. In embodiments, the resistance difference between the two resistance values may be one or more orders of magnitude.

In various embodiments, the RRAM memory cells, e.g., the RRAM memory cell 102, the RRAM memory cell 112, the RRAM memory cell 122, and the RRAM memory cell 132, included in the RRAM array 100 may be formed in back-end-of-line (BEOL) processing. Accordingly, the RRAM array 100 may be formed in higher metal layers, e.g., metal layer three and/or metal layer four, of the integrated circuit above the active substrate region, and may not occupy the active substrate area that is occupied by conventional transistors or memory devices.

FIGS. 2(a)-2(c) schematically illustrate a three-dimensional view or cross-section views of a RRAM memory cell 202 including a diode 205 and a RRAM storage cell 203, in accordance with various embodiments. The RRAM memory cell 202, the diode 205, and the RRAM storage cell 203 may be similar to the RRAM memory cell 102, the diode 105, and the RRAM storage cell 103 as shown in FIG. 1.

In embodiments, as shown in FIG. 2(b), the RRAM memory cell 202 includes the diode 205 and the RRAM storage cell 203 with a shared electrode 204. In detail, the RRAM storage cell 203 includes a first electrode 201 located in a first metal layer above a substrate, a resistive switching material layer 211 adjacent to the first electrode 201, and the shared electrode 204 that may be a second electrode for the RRAM storage cell 203. Furthermore, the diode 205 includes the shared electrode 204, a semiconductor layer 208 adjacent to the shared electrode 204, and a third electrode 207 located in a second metal layer above the substrate.

In embodiments, the first electrode 201 of the RRAM storage cell 203 may be a bit line of a RRAM array, and the third electrode 207 of the diode 205 may be a word line of the RRAM array. Furthermore, the first electrode 201, the shared electrode 204, and the third electrode 207 may be of a shape selected from a group consisting of a rectangular shape, a square shape, an oval shape, a circular shape, a triangular shape, a staircase shape, a trapezoid shape, and a polygon shape. In addition, the first electrode 201, the shared electrode 204, and the third electrode 207 may include a material selected from a group consisting of germanium (Ge), cobalt (Co), titanium (Ti), tungsten (W), molybdenum (Mo), gold (Au), platinum (Pt), aluminum (Al), nickel (Ni), copper (Cu), chromium (Cr), hafnium (Hf), indium (In), ruthenium (Ru), iridium (Ir), tantalum (Ta), and an alloy of Ti, W, Mo, Au, Pt, Al, Ni, Cu, Cr, Hf, HfAlN, iridium-tantalum alloy (Ir—Ta), indium-tin oxide (ITO), TaN, TiN, TiAlN, TiW, or InAlO.

In embodiments, the resistive switching material layer 211, or the semiconductor layer 208 may have a thickness in a range of about 1-20 nm. The resistive switching material layer 211 may include a material selected from a group consisting of HfOx, TaOx, HfTaOx, AlOₓ, GdOₓ, TiOₓ, NiOₓ, ZrOₓ, ZnO, SiOₓ, GeOₓ, Te, Ge, Si, and chalcogenide. Additionally and alternatively, the resistive switching material layer 211 may include a transition metal oxide or a transition metal chalcogenide. On the other hand, the semiconductor layer 208 may include a material selected from a group consisting of ZnO, InOx, GaOx, IGZO, IZO, ITO, SnOx, Cu2O, CuO, CoO, amorphous Si, amorphous Ge, polysilicon, a transition metal chalcogenide, and a transition metal oxide.

In embodiments, as shown in FIG. 2(c), the RRAM storage cell 203 may include an interfacial layer 209 adjacent to the resistive switching material layer 211, and between the first electrode 201 and the shared electrode 204. The interfacial layer 209 may include a material selected from a group consisting of AlOₓ, GdOₓ, HfOₓ, TaOₓ, and high-κ oxide.

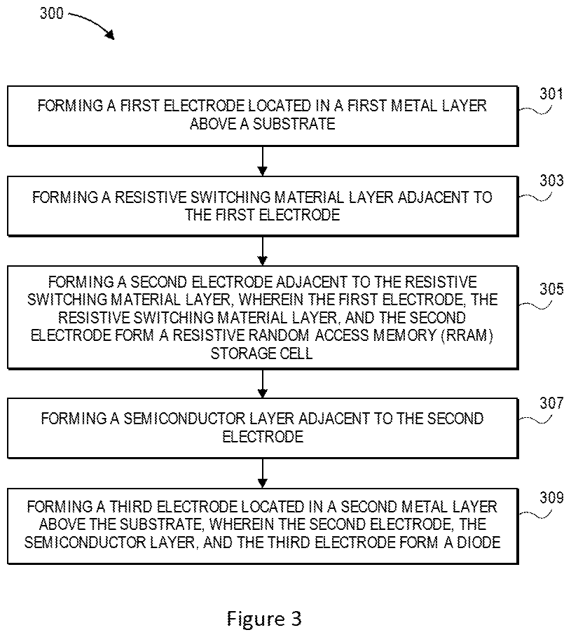

FIG. 3 illustrates a diagram of a process 300 for forming a RRAM memory cell including a diode and a RRAM storage cell, in accordance with some embodiments. In embodiments, the process 300 may be applied to form the RRAM memory cell 102, the RRAM memory cell 112, the RRAM memory cell 122, and the RRAM memory cell 132 as shown in FIG. 1, or the RRAM memory cell 202 as shown in FIGS. 2(a)-2(c).

At block 301, the process 300 may include forming a first electrode located in a first metal layer above a substrate. For example, the process 300 may include forming the first electrode 201 located in a first metal layer above a substrate as shown in FIG. 2(a).

At block 303, the process 300 may include forming a resistive switching material layer adjacent to the first electrode. For example, the process 300 may include forming the resistive switching material layer 211 adjacent to the first electrode 201 as shown in FIG. 2(a).

At block 305, the process 300 may include forming a second electrode adjacent to the resistive switching material layer, where the first electrode, the resistive switching material layer, and the second electrode form a RRAM storage cell. For example, the process 300 may include forming the shared electrode 204 adjacent to the resistive switching material layer 211. The first electrode 201, the resistive switching material layer 211, and the shared electrode 204 form the RRAM storage cell 203 as shown in FIG. 2(a).

At block 307, the process 300 may include forming a semiconductor layer adjacent to the second electrode. For example, the process 300 may include forming the semiconductor layer 208 adjacent to the shared electrode 204 as shown in FIG. 2(a).

At block 309, the process 300 may include forming a third electrode located in a second metal layer above the substrate, wherein the second electrode, the semiconductor layer, and the third electrode form a diode. For example, the process 300 may include forming the third electrode 207 located in a second metal layer above the substrate. The shared electrode 204, the semiconductor layer 208, and the third electrode 207 form the diode 205 as shown in FIG. 2(a).

In addition, the process 300 may include additional operations to form other layers, e.g., ILD layers, encapsulation layers, insulation layers, not shown.

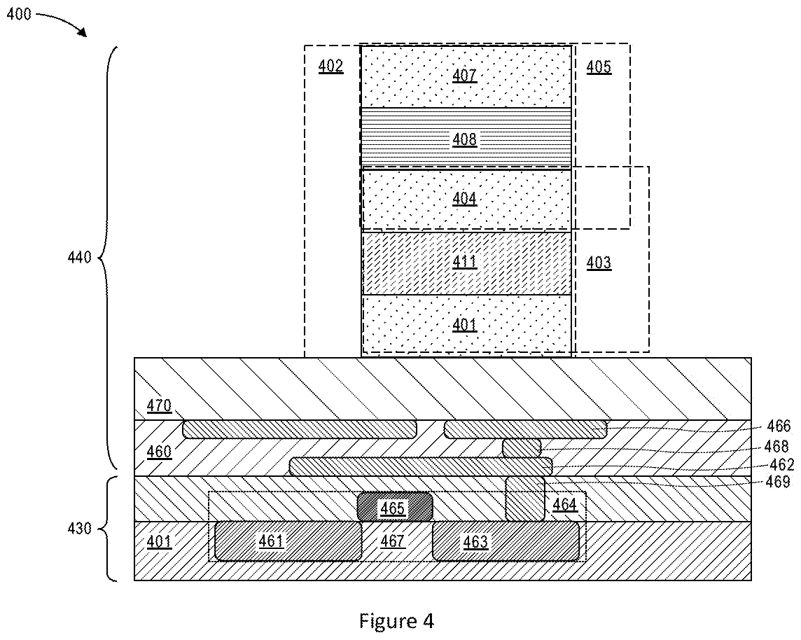

FIG. 4 schematically illustrates a diagram of a RRAM memory cell 402 including a diode 405 and a RRAM storage cell 403 formed in back-end-of-line (BEOL) on a substrate 401, in accordance with some embodiments. The RRAM memory cell 402 may be an example of the RRAM memory cell 102, the RRAM memory cell 112, the RRAM memory cell 122, and the RRAM memory cell 132 as shown in FIG. 1, the RRAM memory cell 202 as shown in FIGS. 2(a)-2(c).

In embodiments, an IC 400 includes the substrate 401, and the RRAM memory cell 402 above the substrate 401. The RRAM memory cell 402 includes the diode 405 and the RRAM storage cell 403 with a shared electrode 404. In detail, the RRAM storage cell 403 includes a first electrode 401 located in a first metal layer above the substrate 401, a resistive switching material layer 411 adjacent to the first electrode 401, and the shared electrode 404 that may be a second electrode for the RRAM storage cell 403. Furthermore, the diode 405 includes the shared electrode 404, a semiconductor layer 408 adjacent to the shared electrode 404, and a third electrode 407 located in a second metal layer above the substrate 401.

In embodiments, the RRAM memory cell 402 may be formed at the BEOL 440. In addition to the RRAM memory cell 402, the BEOL 440 may further include a dielectric layer 460 and a dielectric layer 470. One or more vias, e.g., a via 468, may be connected to one or more interconnect, e.g., an interconnect 466, and an interconnect 462 within the dielectric layer 460. In embodiments, the interconnect 466 and the interconnect 462 may be of different metal layers at the BEOL 440. The dielectric layer 460 is shown for example only. Although not shown by FIG. 4, in various embodiments there may be multiple dielectric layers included in the BEOL 440.

In embodiments, the BEOL 440 may be formed on the front-end-of-line (FEOL) 430. The FEOL 430 may include the substrate 401. In addition, the FEOL 430 may include other devices, e.g., a transistor 464. In embodiments, the transistor 464 may be a FEOL transistor, including a source 461, a drain 463, and a gate 465, with a channel 467 between the source 461 and the drain 463 under the gate 465. Furthermore, the transistor 464 may be coupled to interconnects, e.g., the interconnect 462, through a via 469.

In embodiments, the substrate 401 may be a silicon substrate, a glass substrate, such as soda lime glass or borosilicate glass, a metal substrate, a plastic substrate, a bulk substrate, a silicon-on-insulator (SOI) substrate, or another suitable substrate. Other dielectric layer or other devices may be formed on the substrate 401, not shown for clarity.

In embodiments, the ILD layer 460 or the ILD layer 470 may include silicon dioxide (SiO₂), carbon doped oxide (CDO), silicon nitride, perfluorocyclobutane, polytetrafluoroethylene, fluorinated silicate glass (FSG), organic polymer, siloxane, a porous dielectric material, or organosilicate glass. In some embodiments, the ILD layer 460 or the ILD layer 470 may include some low-k dielectric materials. Suitable dielectric materials may include carbon-doped silicon dioxide materials, organic polymeric thermoset materials, silicon oxycarbide; SiCOH dielectrics; fluorine doped silicon oxide; spin-on glasses, silsesquioxanes, including hydrogen silsesquioxane (HSQ), methyl silsesquioxane (MSQ) and mixtures or copolymers of HSQ and MSQ; benzocyclobutene (BCB)-based polymer dielectrics, and any silicon-containing low-k dielectric material.

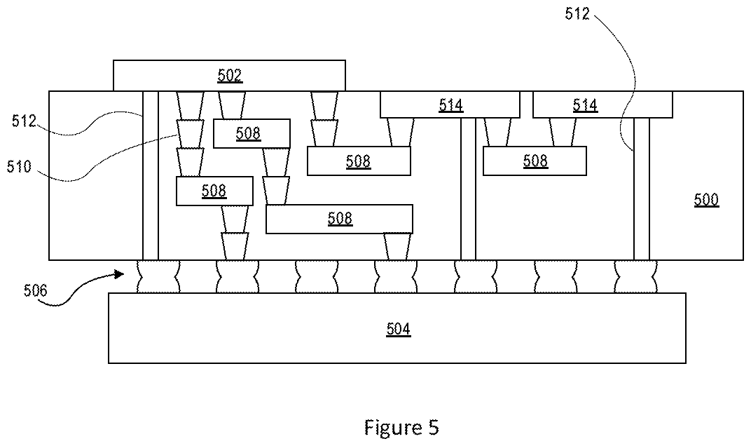

FIG. 5 schematically illustrates an interposer 500 implementing one or more embodiments of the disclosure, in accordance with some embodiments. The interposer 500 is an intervening substrate used to bridge a first substrate 502 to a second substrate 504. The first substrate 502 may be, for instance, a substrate support for a RRAM memory cell, e.g., the RRAM memory cell 102, the RRAM memory cell 112, the RRAM memory cell 122, and the RRAM memory cell 132 as shown in FIG. 1, the RRAM memory cell 202 as shown in FIGS. 2(a)-2(c), the RRAM memory cell 402 as shown in FIG. 4, or a RRAM memory cell formed according to the process 300 shown in FIG. 3. The second substrate 504 may be, for instance, a memory module, a computer motherboard, or another integrated circuit die. For example, the second substrate 504 may be a memory module including the RRAM array 100 as shown in FIG. 1. Generally, the purpose of an interposer 500 is to spread a connection to a wider pitch or to reroute a connection to a different connection. For example, an interposer 500 may couple an integrated circuit die to a ball grid array (BGA) 506 that can subsequently be coupled to the second substrate 504. In some embodiments, the first and second substrates 502/504 are attached to opposing sides of the interposer 500. In other embodiments, the first and second substrates 502/504 are attached to the same side of the interposer 500. And in further embodiments, three or more substrates are interconnected by way of the interposer 500.

The interposer 500 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 508 and vias 510, including but not limited to through-silicon vias (TSVs) 512. The interposer 500 may further include embedded devices 514, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 500.

In accordance with embodiments of the disclosure, apparatuses or processes disclosed herein may be used in the fabrication of interposer 500.

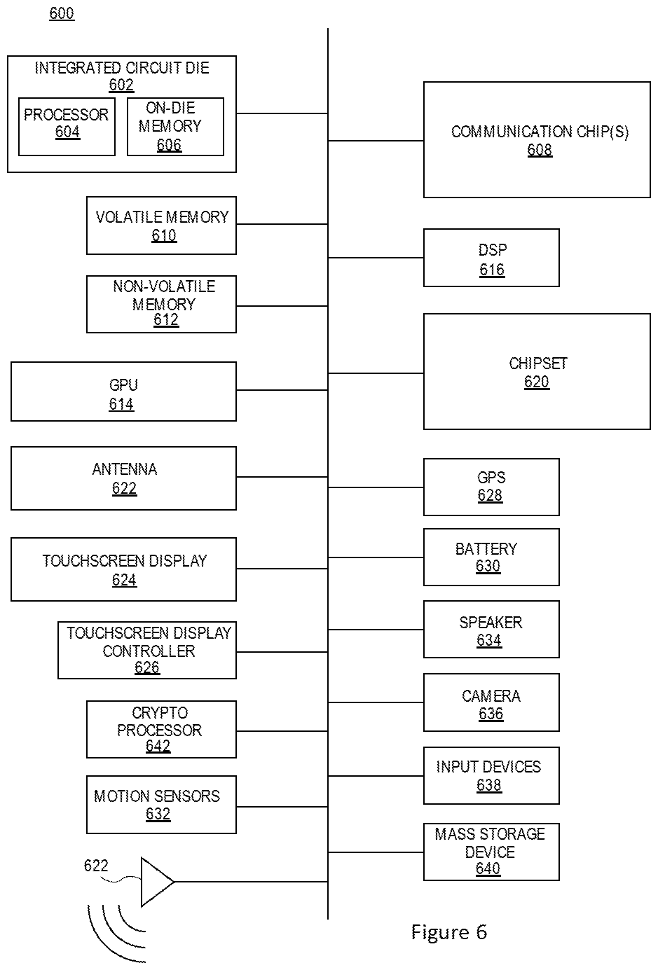

FIG. 6 illustrates a computing device 600 in accordance with one embodiment of the disclosure. The computing device 600 may include a number of components. In one embodiment, these components are attached to one or more motherboards. In an alternate embodiment, some or all of these components are fabricated onto a single system-on-a-chip (SoC) die, such as a SoC used for mobile devices. The components in the computing device 600 include, but are not limited to, an integrated circuit die 602 and at least one communications logic unit 608. In some implementations the communications logic unit 608 is fabricated within the integrated circuit die 602 while in other implementations the communications logic unit 608 is fabricated in a separate integrated circuit chip that may be bonded to a substrate or motherboard that is shared with or electronically coupled to the integrated circuit die 602. The integrated circuit die 602 may include a processor 604 as well as on-die memory 606, often used as cache memory, which can be provided by technologies such as embedded DRAM (eDRAM), or SRAM. For example, the on-die memory 606 may include the RRAM memory cell 102, the RRAM memory cell 112, the RRAM memory cell 122, and the RRAM memory cell 132 as shown in FIG. 1, the RRAM memory cell 202 as shown in FIGS. 2(a)-2(c), the RRAM memory cell 402 as shown in FIG. 4, or a RRAM memory cell formed according to the process 300 shown in FIG. 3.

In embodiments, the computing device 600 may include a display or a touchscreen display 624, and a touchscreen display controller 626. A display or the touchscreen display 624 may include a FPD, an AMOLED display, a TFT LCD, a micro light-emitting diode (LED) display, or others. For example, the touchscreen display 624 may include the RRAM memory cell 102, the RRAM memory cell 112, the RRAM memory cell 122, and the RRAM memory cell 132 as shown in FIG. 1, the RRAM memory cell 202 as shown in FIGS. 2(a)-2(c), the RRAM memory cell 402 as shown in FIG. 4, or a RRAM memory cell formed according to the process 300 shown in FIG. 3.

Computing device 600 may include other components that may or may not be physically and electrically coupled to the motherboard or fabricated within a SoC die. These other components include, but are not limited to, volatile memory 610 (e.g., dynamic random access memory (DRAM), non-volatile memory 612 (e.g., ROM or flash memory), a graphics processing unit 614 (GPU), a digital signal processor (DSP) 616, a crypto processor 642 (e.g., a specialized processor that executes cryptographic algorithms within hardware), a chipset 620, at least one antenna 622 (in some implementations two or more antenna may be used), a battery 630 or other power source, a power amplifier (not shown), a voltage regulator (not shown), a global positioning system (GPS) device 628, a compass, a motion coprocessor or sensors 632 (that may include an accelerometer, a gyroscope, and a compass), a microphone (not shown), a speaker 634, a camera 636, user input devices 638 (such as a keyboard, mouse, stylus, and touchpad), and a mass storage device 640 (such as hard disk drive, compact disk (CD), digital versatile disk (DVD), and so forth). The computing device 600 may incorporate further transmission, telecommunication, or radio functionality not already described herein. In some implementations, the computing device 600 includes a radio that is used to communicate over a distance by modulating and radiating electromagnetic waves in air or space. In further implementations, the computing device 600 includes a transmitter and a receiver (or a transceiver) that is used to communicate over a distance by modulating and radiating electromagnetic waves in air or space.

The communications logic unit 608 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications logic unit 608 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Infrared (IR), Near Field Communication (NFC), Bluetooth, derivatives thereof, as well as any other wireless protocols that are designated as 3G, 4G, 5G, and beyond. The computing device 600 may include a plurality of communications logic units 608. For instance, a first communications logic unit 608 may be dedicated to shorter range wireless communications such as Wi-Fi, NFC, and Bluetooth and a second communications logic unit 608 may be dedicated to longer range wireless communications such as GPS, EDGE, GPRS, CDMA, WiMAX, LTE, Ev-DO, and others.

The processor 604 of the computing device 600 includes one or more devices, such as transistors. The term “processor” may refer to any device or portion of a device that processes electronic data from registers and/or memory to transform that electronic data into other electronic data that may be stored in registers and/or memory. The communications logic unit 608 may also include one or more devices, such as transistors.

In further embodiments, another component housed within the computing device 600 may contain one or more devices, such as DRAM, that are formed in accordance with implementations of the current disclosure, e.g., the RRAM memory cell 102, the RRAM memory cell 112, the RRAM memory cell 122, and the RRAM memory cell 132 as shown in FIG. 1, the RRAM memory cell 202 as shown in FIGS. 2(a)-2(c), the RRAM memory cell 402 as shown in FIG. 4, or a RRAM memory cell formed according to the process 300 shown in FIG. 3.

In various embodiments, the computing device 600 may be a laptop computer, a netbook computer, a notebook computer, an ultrabook computer, a smartphone, a dumbphone, a tablet, a tablet/laptop hybrid, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

Some non-limiting Examples are provided below.

Example 1 may include a resistive random access memory (RRAM) device, comprising: a substrate; a RRAM storage cell, including: a first electrode located in a first metal layer above the substrate; a resistive switching material layer adjacent to the first electrode; and a second electrode adjacent to the resistive switching material layer; and a diode adjacent to the RRAM storage cell, including: the second electrode shared with the RRAM storage cell; a semiconductor layer adjacent to the second electrode; and a third electrode located in a second metal layer above the substrate.

Example 2 may include the RRAM device of example 1 and/or some other examples herein, wherein the resistive switching material layer includes a material selected from a group consisting of HfOx, TaOx, HfTaOx, AlOx, GdOx, TiOx, NiOx, ZrOx, ZnO, SiOx, GeOx, Te, Ge, Si, and chalcogenide.

Example 3 may include the RRAM device of example 1 and/or some other examples herein, wherein the resistive switching material layer includes a transition metal oxide or a transition metal chalcogenide.

Example 4 may include the RRAM device of example 1 and/or some other examples herein, wherein the semiconductor layer of the diode includes a material selected from a group consisting of ZnO, InOx, GaOx, IGZO, IZO, ITO, SnOx, Cu2O, CuO, CoO, amorphous Si, amorphous Ge, polysilicon, a transition metal chalcogenide, and a transition metal oxide.

Example 5 may include the RRAM device of example 1 and/or some other examples herein, wherein the resistive switching material layer, or the semiconductor layer has a thickness in a range of about 1-20 nm.

Example 6 may include the RRAM device of example 1 and/or some other examples herein, wherein the first electrode, the second electrode, and the third electrode is of a shape selected from a group consisting of a rectangular shape, a square shape, an oval shape, a circular shape, a triangular shape, a staircase shape, a trapezoid shape, and a polygon shape.

Example 7 may include the RRAM device of example 1 and/or some other examples herein, wherein RRAM storage cell further includes an interfacial layer adjacent to the resistive switching material layer, and between the first electrode and the second electrode.

Example 8 may include the RRAM device of example 7 and/or some other examples herein, wherein the interfacial layer includes a material selected from a group consisting of AlOx, GdOx, HfOx, TaOx, and high-κ oxide.

Example 9 may include the RRAM device of example 1 and/or some other examples herein, wherein the first electrode is a bit line of a RRAM array, and the third electrode is a word line of the RRAM array.

Example 10 may include the RRAM device of example 1 and/or some other examples herein, wherein the substrate is a bulk substrate or a silicon-on-insulator (SOI) substrate.

Example 11 may include the RRAM device of example 1 and/or some other examples herein, wherein the first electrode, the second electrode, or the third electrode includes a material selected from a group consisting of germanium (Ge), cobalt (Co), titanium (Ti), tungsten (W), molybdenum (Mo), gold (Au), platinum (Pt), aluminum (Al), nickel (Ni), copper (Cu), chromium (Cr), hafnium (Hf), indium (In), ruthenium (Ru), iridium (Ir), tantalum (Ta), and an alloy of Ti, W, Mo, Au, Pt, Al, Ni, Cu, Cr, Hf, HfAlN, iridium-tantalum alloy (Ir—Ta), indium-tin oxide (ITO), TaN, TiN, TiAlN, TiW, or InAlO.

Example 12 may include a resistive random access memory (RRAM) array, comprising: a plurality of RRAM memory cells, wherein a RRAM memory cell of the plurality of RRAM memory cells includes a diode and a RRAM storage cell and is coupled to a bit line and a word line; wherein the RRAM storage cell includes: a first electrode located in a first metal layer above a substrate, wherein the first electrode is coupled to the bit line; a resistive switching material layer adjacent to the first electrode; and a second electrode adjacent to the resistive switching material layer; the diode is adjacent to the RRAM storage cell and includes: the second electrode shared with the RRAM storage cell; a semiconductor layer adjacent to the second electrode; and a third electrode located in a second metal layer above the substrate, wherein the third electrode is coupled to the word line of the RRAM array.

Example 13 may include the RRAM array of example 12 and/or some other examples herein, wherein the resistive switching material layer includes a material selected from a group consisting of HfOx, TaOx, HfTaOx, AlOx, GdOx, TiOx, NiOx, ZrOx, ZnO, SiOx, GeOx, Te, Ge, Si, and chalcogenide.

Example 14 may include the RRAM array of example 12 and/or some other examples herein, wherein the semiconductor layer of the diode includes a material selected from a group consisting of ZnO, InOx, GaOx, IGZO, IZO, ITO, SnOx, Cu2O, CuO, CoO, amorphous Si, amorphous Ge, polysilicon, a transition metal chalcogenide, and a transition metal oxide.

Example 15 may include the RRAM array of example 12 and/or some other examples herein, wherein the first electrode, the second electrode, or the third electrode includes a material selected from a group consisting of germanium (Ge), cobalt (Co), titanium (Ti), tungsten (W), molybdenum (Mo), gold (Au), platinum (Pt), aluminum (Al), nickel (Ni), copper (Cu), chromium (Cr), hafnium (Hf), indium (In), ruthenium (Ru), iridium (Ir), tantalum (Ta), and an alloy of Ti, W, Mo, Au, Pt, Al, Ni, Cu, Cr, Hf, HfAlN, iridium-tantalum alloy (Ir—Ta), indium-tin oxide (ITO), TaN, TiN, TiAlN, TiW, or InAlO.

Example 16 may include the RRAM array of example 12 and/or some other examples herein, wherein the resistive switching material layer, or the semiconductor layer has a thickness in a range of about 1-20 nm.

Example 17 may include a method for forming a resistive random access memory (RRAM) device, the method comprising: forming a first electrode located in a first metal layer above a substrate; forming a resistive switching material layer adjacent to the first electrode; and forming a second electrode adjacent to the resistive switching material layer, wherein the first electrode, the resistive switching material layer, and the second electrode form a RRAM storage cell; forming a semiconductor layer adjacent to the second electrode; and forming a third electrode located in a second metal layer above the substrate, wherein the second electrode, the semiconductor layer, and the third electrode form a diode.

Example 18 may include the method of example 17 and/or some other examples herein, wherein the resistive switching material layer includes a material selected from a group consisting of HfOx, TaOx, HfTaOx, AlOx, GdOx, TiOx, NiOx, ZrOx, ZnO, SiOx, GeOx, Te, Ge, Si, and chalcogenide.

Example 19 may include the method of example 17 and/or some other examples herein, wherein the resistive switching material layer includes a transition metal oxide or a transition metal chalcogenide.

Example 20 may include the method of example 17 and/or some other examples herein, wherein the semiconductor layer of the diode includes a material selected from a group consisting of ZnO, InOx, GaOx, IGZO, IZO, ITO, SnOx, Cu2O, CuO, CoO, amorphous Si, amorphous Ge, polysilicon, a transition metal chalcogenide, and a transition metal oxide.

Example 21 may include a computing device, comprising: a circuit board; and a memory device coupled to the circuit board and including a plurality of resistive random access memory (RRAM) memory cells, wherein a RRAM memory cell of the plurality of RRAM memory cells includes a diode and a RRAM storage cell and is coupled to a bit line and a word line; wherein the RRAM storage cell includes: a first electrode located in a first metal layer above a substrate, wherein the first electrode is coupled to the bit line; a resistive switching material layer adjacent to the first electrode; and a second electrode adjacent to the resistive switching material layer; the diode is adjacent to the RRAM storage cell and includes: the second electrode shared with the RRAM storage cell; a semiconductor layer adjacent to the second electrode; and a third electrode located in a second metal layer above the substrate, wherein the third electrode is coupled to the word line of the RRAM array.

Example 22 may include computing device of example 21 and/or some other examples herein, wherein the resistive switching material layer includes a material selected from a group consisting of HfOx, TaOx, HfTaOx, AlOx, GdOx, TiOx, NiOx, ZrOx, ZnO, SiOx, GeOx, Te, Ge, Si, and chalcogenide.

Example 23 may include computing device of example 21 and/or some other examples herein, wherein the resistive switching material layer includes a transition metal oxide or a transition metal chalcogenide.

Example 24 may include computing device of example 21 and/or some other examples herein, wherein the semiconductor layer of the diode includes a material selected from a group consisting of ZnO, InOx, GaOx, IGZO, IZO, ITO, SnOx, Cu2O, CuO, CoO, amorphous Si, amorphous Ge, polysilicon, a transition metal chalcogenide, and a transition metal oxide.

Example 25 may include computing device of example 21 and/or some other examples herein, wherein the computing device is a wearable device or a mobile computing device, the wearable device or the mobile computing device including one or more of an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, or a camera coupled with the circuit board.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

What is claimed is:

1. A resistive random access memory (RRAM) device, comprising:
a substrate;
a RRAM storage cell, including:
a first electrode located in a first metal layer above the substrate;
a resistive switching material layer adjacent to the first electrode; and
a second electrode adjacent to the resistive switching material layer; and
a diode adjacent to the RRAM storage cell, including:
the second electrode shared with the RRAM storage cell;
a semiconductor layer adjacent to the second electrode; and
a third electrode located in a second metal layer above the substrate.

2. The RRAM device of claim 1, wherein the resistive switching material layer includes a material selected from a group consisting of HfOx, TaOx, HfTaOx, AlOₓ, GdOₓ, TiOₓ, NiOₓ, ZrOₓ, ZnO, SiOₓ, GeOₓ, Te, Ge, Si, and chalcogenide.

3. The RRAM device of claim 1, wherein the resistive switching material layer includes a transition metal oxide or a transition metal chalcogenide.

4. The RRAM device of claim 1, wherein the semiconductor layer of the diode includes a material selected from a group consisting of ZnO, InOx, GaOx, IGZO, IZO, ITO, SnOx, Cu2O, CuO, CoO, amorphous Si, amorphous Ge, polysilicon, a transition metal chalcogenide, and a transition metal oxide.

5. The RRAM device of claim 1, wherein the resistive switching material layer, or the semiconductor layer has a thickness in a range of about 1-20 nm.

6. The RRAM device of claim 1, wherein the first electrode, the second electrode, and the third electrode is of a shape selected from a group consisting of a rectangular shape, a square shape, an oval shape, a circular shape, a triangular shape, a staircase shape, a trapezoid shape, and a polygon shape.

7. The RRAM device of claim 1, wherein RRAM storage cell further includes an interfacial layer adjacent to the resistive switching material layer, and between the first electrode and the second electrode.

8. The RRAM device of claim 7, wherein the interfacial layer includes a material selected from a group consisting of AlOₓ, GdOₓ, HfOₓ, TaOₓ, and high-κ oxide.

9. The RRAM device of claim 1, wherein the first electrode is a bit line of a RRAM array, and the third electrode is a word line of the RRAM array.

10. The RRAM device of claim 1, wherein the substrate is a bulk substrate or a silicon-on-insulator (SOI) substrate.

11. The RRAM device of claim 1, wherein the first electrode, the second electrode, or the third electrode includes a material selected from a group consisting of germanium (Ge), cobalt (Co), titanium (Ti), tungsten (W), molybdenum (Mo), gold (Au), platinum (Pt), aluminum (Al), nickel (Ni), copper (Cu), chromium (Cr), hafnium (Hf), indium (In), ruthenium (Ru), iridium (Ir), tantalum (Ta), and an alloy of Ti, W, Mo, Au, Pt, Al, Ni, Cu, Cr, Hf, HfAlN, iridium-tantalum alloy (Ir—Ta), indium-tin oxide (ITO), TaN, TiN, TiAlN, TiW, or InAlO.

12. A resistive random access memory (RRAM) array, comprising:
a plurality of RRAM memory cells, wherein a RRAM memory cell of the plurality of RRAM memory cells includes a diode and a RRAM storage cell and is coupled to a bit line and a word line;
wherein the RRAM storage cell includes:
a first electrode located in a first metal layer above a substrate, wherein the first electrode is coupled to the bit line;
a resistive switching material layer adjacent to the first electrode; and
a second electrode adjacent to the resistive switching material layer;
the diode is adjacent to the RRAM storage cell and includes:
the second electrode shared with the RRAM storage cell;
a semiconductor layer adjacent to the second electrode; and
a third electrode located in a second metal layer above the substrate, wherein the third electrode is coupled to the word line of the RRAM array.

13. The RRAM array of claim 12, wherein the resistive switching material layer includes a material selected from a group consisting of HfOx, TaOx, HfTaOx, AlOₓ, GdOₓ, TiOₓ, NiOₓ, ZrOₓ, ZnO, SiOₓ, GeOₓ, Te, Ge, Si, and chalcogenide.

14. The RRAM array of claim 12, wherein the semiconductor layer of the diode includes a material selected from a group consisting of ZnO, InOx, GaOx, IGZO, IZO, ITO, SnOx, Cu2O, CuO, CoO, amorphous Si, amorphous Ge, polysilicon, a transition metal chalcogenide, and a transition metal oxide.

15. The RRAM array of claim 12, wherein the first electrode, the second electrode, or the third electrode includes a material selected from a group consisting of germanium (Ge), cobalt (Co), titanium (Ti), tungsten (W), molybdenum (Mo), gold (Au), platinum (Pt), aluminum (Al), nickel (Ni), copper (Cu), chromium (Cr), hafnium (Hf), indium (In), ruthenium (Ru), iridium (Ir), tantalum (Ta), and an alloy of Ti, W, Mo, Au, Pt, Al, Ni, Cu, Cr, Hf, HfAlN, iridium-tantalum alloy (Ir—Ta), indium-tin oxide (ITO), TaN, TiN, TiAlN, TiW, or InAlO.

16. The RRAM array of claim 12, wherein the resistive switching material layer, or the semiconductor layer has a thickness in a range of about 1-20 nm.

17. A method for forming a resistive random access memory (RRAM) device, the method comprising:
forming a first electrode located in a first metal layer above a substrate;
forming a resistive switching material layer adjacent to the first electrode; and
forming a second electrode adjacent to the resistive switching material layer, wherein the first electrode, the resistive switching material layer, and the second electrode form a RRAM storage cell;
forming a semiconductor layer adjacent to the second electrode; and
forming a third electrode located in a second metal layer above the substrate, wherein the second electrode, the semiconductor layer, and the third electrode form a diode.

18. The method of claim 17, wherein the resistive switching material layer includes a material selected from a group consisting of HfOx, TaOx, HfTaOx, AlOₓ, GdOₓ, TiOₓ, NiOₓ, ZrOₓ, ZnO, SiOₓ, GeOₓ, Te, Ge, Si, and chalcogenide.

19. The method of claim 17, wherein the resistive switching material layer includes a transition metal oxide or a transition metal chalcogenide.

20. The method of claim 17, wherein the semiconductor layer of the diode includes a material selected from a group consisting of ZnO, InOx, GaOx, IGZO, IZO, ITO, SnOx, Cu2O, CuO, CoO, amorphous Si, amorphous Ge, polysilicon, a transition metal chalcogenide, and a transition metal oxide.

21. A computing device, comprising:
a circuit board; and
a memory device coupled to the circuit board and including a plurality of resistive random access memory (RRAM) memory cells, wherein a RRAM memory cell of the plurality of RRAM memory cells includes a diode and a RRAM storage cell and is coupled to a bit line and a word line;
wherein the RRAM storage cell includes:
a first electrode located in a first metal layer above a substrate, wherein the first electrode is coupled to the bit line;
a resistive switching material layer adjacent to the first electrode; and
a second electrode adjacent to the resistive switching material layer;
the diode is adjacent to the RRAM storage cell and includes:
the second electrode shared with the RRAM storage cell;
a semiconductor layer adjacent to the second electrode; and
a third electrode located in a second metal layer above the substrate, wherein the third electrode is coupled to the word line of the RRAM array.

22. The computing device of claim 21, wherein the resistive switching material layer includes a material selected from a group consisting of HfOx, TaOx, HfTaOx, AlOₓ, GdOₓ, TiOₓ, NiOₓ, ZrOₓ, ZnO, SiOₓ, GeOₓ, Te, Ge, Si, and chalcogenide.

23. The computing device of claim 21, wherein the resistive switching material layer includes a transition metal oxide or a transition metal chalcogenide.

24. The computing device of claim 21, wherein the semiconductor layer of the diode includes a material selected from a group consisting of ZnO, InOx, GaOx, IGZO, IZO, ITO, SnOx, Cu2O, CuO, CoO, amorphous Si, amorphous Ge, polysilicon, a transition metal chalcogenide, and a transition metal oxide.

25. The computing device of claim 21, wherein the computing device is a wearable device or a mobile computing device, the wearable device or the mobile computing device including one or more of an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, or a camera coupled with the circuit board.
